(19) United States
(12) Patent Application Publication
(10) Pub. No.: US 2012/0228241 A1
(43) Pub. Date: Sep. 13, 2012

(54) STAND APPARATUS

(75) Inventor: Motoharu AKITA, Osaka (JP)

(73) Assignee: SHARP KABUSHIKI KAISHA, Osaka (JP)

(21) Appl. No.: 13/413,749

(22) Filed: Mar. 7, 2012

(30) Foreign Application Priority Data
Mar. 10, 2011 (JP) 2011-53638

(51) Int. Cl. H05K 7/18

(52) U.S. Cl. 211/1.57; 211/26

(57) ABSTRACT

A stand apparatus capable of improving maintainability of a multi-display apparatus is provided. A stand apparatus includes a column, a plurality of holding members configured to be able to hold image display units and be mounted to the column so as to be capable of ascending and descending along an axial line of the column, the plurality of holding members including a reference holding member supported by the column in a state of being restricted to move at least in a direction of descending along the axial line of the column, and a movable holding member supported by the column so as to be freely elevated and lowered along the axial line of the column, and an elevating and lowering section configured so as to elevate and lower the movable holding member along the axial line of the column.

### BACKGROUND OF THE TECHNOLOGY

1. Field of the Technology The present technology relates to a stand apparatus used for installing a multi-display apparatus in public places.

2. Description of the Related Art

In recent years, as an information display and a business display, a multi-display apparatus has been used that is capable of displaying one large image as a whole by arranging a plurality of image display units provided with a display panel capable of displaying an image longitudinally and transversely in a plane.

In response thereto, various apparatuses used for installing a multi-display apparatus have been also proposed. For example, Japanese Unexamined Patent Publication JP-A 2001-202031 proposes an apparatus for installing a multi-display apparatus on a wall face.

A multi-display apparatus is configured by arranging a plurality of image display units in a plane with almost no space, and when being installed on an installation object such as a wall face, by hooking a hooking section in an inverted J-shape which is coupled to a back face thereof with a hooked section which is fixed in advance to the installation object, as shown in JP-A 2001-202031, each of the image display units is attached to the hooked section.

By the way, when an image display unit is attached in such a state, in order to remove the image display unit from the hooked section, it becomes necessary to displace the image display unit upward relative to the hooked section to detach the hooking section coupled to the image display unit from the hooked section.

However, since image display units are arranged with no space in a multi-display apparatus as described above, when trying to remove an image display unit arranged at a bottom stage, for example, to carry out maintenance, an image display unit arranged at its upper stage inhibits upward displacement, so that it is impossible to remove only the image display unit to be removed.

In this manner, at the time of carrying out maintenance of the multi-display apparatus, there is a case where for removing the image display unit to be removed, other image display unit has to be removed, and in such a case, there is a problem that excess labor and time are required.

### SUMMARY OF THE TECHNOLOGY

An object of the technology is to provide a stand apparatus capable of improving maintainability of a multi-display apparatus.

The technology provides a stand apparatus for installing a multi-display apparatus having a configuration such that a plurality of image display units are arranged in a plane, including:

a column;

a plurality of holding members configured to be able to hold the image display units and be mounted to the column so as to be capable of ascending and descending along an axial line of the column, the plurality of holding members including
a reference holding member supported by the column in a state of being inhibited to move at least in a direction of descending along the axial line of the column, and
a movable holding member or members supported by the column so as to be freely elevated and lowered along the axial line of the column; and

an elevating and lowering section or sections configured so as to elevate and lower the movable holding member or members along the axial line of the column.

Further, it is preferable that the plurality of holding members each include a movable member attached to the column and a hooking member configured so as to be attachable to the image display unit and capable of being hooked with the movable member, and

the hooking member is configured to be hooked accompanied by displacement along the axial line of the column with respect to the movable member in a state of being attached to the column.

Further, it is preferable that the movable holding members are arranged downward from the reference holing member,

the column is provided with movement restricting members configured so as to restrict movement in a descending direction of the movable holding members for each of the movable holding members, and

the movement restricting members are disposed so that at the lower stage the movable holding members are arranged, the longer movable distances of the movable holding members in the descending direction are.

Further, it is preferable that the movable holding members are arranged upward from the reference holing member, and

the elevating and lowering sections are installed in remaining holding members except a holding member arranged at a top stage, out of the plurality of holding members, respectively.

Further, it is preferable that the elevating and lowering section includes any one of a hydraulic jack, a screw jack, a pneumatic cylinder, a hydraulic cylinder and a winch.

According to the technology, when an image display unit is removed from a multi-display apparatus for executing maintenance, it is possible to remove only the image display unit to be removed without necessity of removing image display units other than the removal object. Accordingly, it is possible to reduce labor and time required for removing the image display unit other than the removal object and to improve maintainability.

### BRIEF DESCRIPTION OF THE DRAWINGS

Other and further objects, features, and advantages of the technology will be more explicit from the following detailed description taken with reference to the drawings wherein:

FIG. 1 is a perspective view of a state where a stand apparatus according to an embodiment supports a multi-display apparatus, seen from a front side;

FIG. 2 is a perspective view of a state where the stand apparatus supports the multi-display apparatus, seen from a back side;

FIG. 3 is a perspective view of a holding member to which the image display unit is attached, seen from the back side;

FIG. 4 is an exploded perspective view showing the holding member;

FIG. 5 is an enlarged perspective view of a holding member arranged at a top stage, seen from the back side;

FIG. 6 is an enraged perspective view of the elevating and lowering section provided in a pair of columns;

FIG. 7 is a perspective view showing a state where a movable plate lowers from a state where the multi-display apparatus is constructed shown in FIG. 6;

FIG. 8 is a perspective view showing a state where an image display unit arranged at a middle stage is removed in the multi-display apparatus; and

FIG. 9 is a perspective view of a state where a stand apparatus according to another embodiment supports a multi-display apparatus, seen from a back side.

### DETAILED DESCRIPTION

Now referring to the drawings, preferred embodiments are described below.

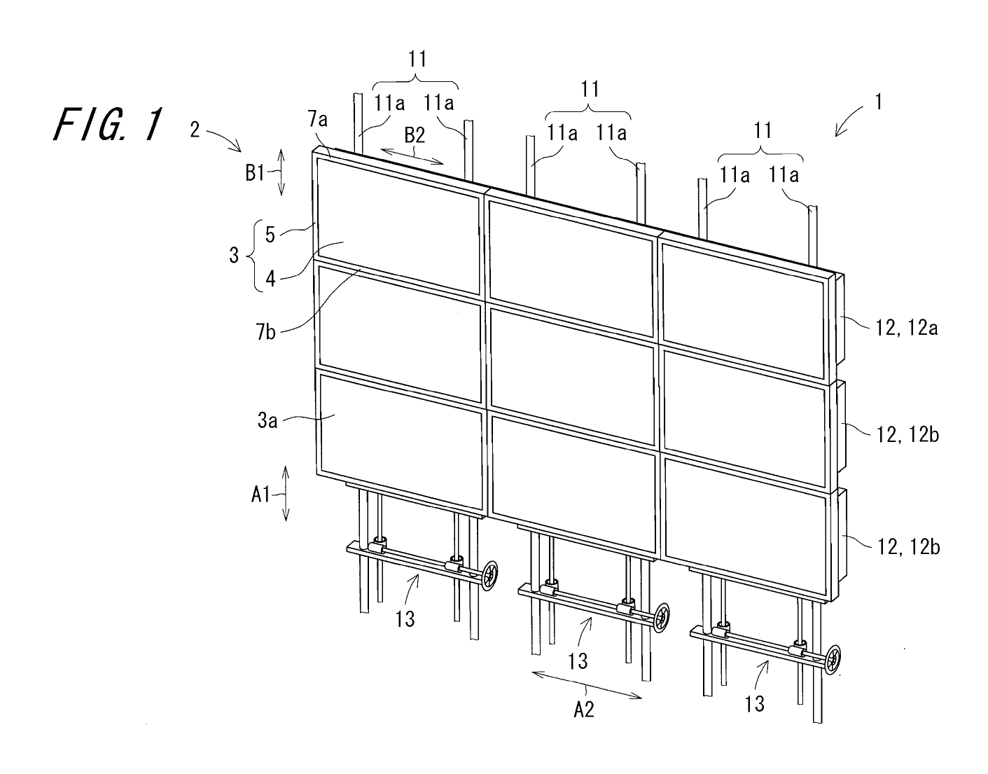

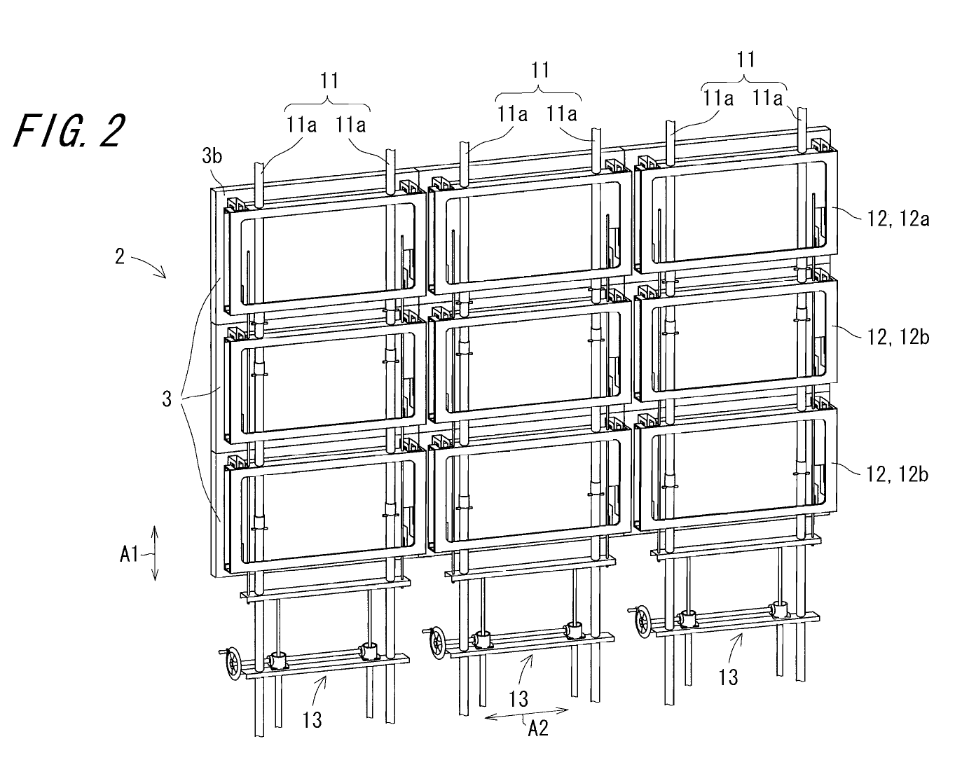

FIG. 1 is a perspective view of a state where a stand apparatus 1 according to an embodiment supports a multi-display apparatus 2, seen from a front side. FIG. 2 is a perspective view of a state where the stand apparatus 1 supports the multi-display apparatus 2, seen from a back side.

The stand apparatus 1 according to this embodiment is an apparatus which is used for installing the multi-display apparatus 2 used as an information display, a business display and the like in public spaces.

The multi-display apparatus 2 to be installed is constructed by arranging a plurality of image display units 3 each of which has the same screen size in a plane so as not to form a space between the image display units 3. In this embodiment, as shown in FIGS. 1 and 2, it is constructed such that nine image display units 3 are arranged with no space in three rows and three columns in a matrix.

Moreover, each of the image display units 3 is arranged in such attitudes that a short side direction B1 thereof matches a vertical direction A1 in the multi-display apparatus 2. Hereinafter, in each of the image display units 3, among both end portions of the short side direction B1, an end portion arranged in the upper end side of the multi-display apparatus 2 is referred to as an “upper end portion” with a reference sign of 7a denoted, and an end portion arranged in the lower end side of the multi-display apparatus 2 is referred to as a “lower end portion” with a reference sign of 7b denoted.

Each of the image display units 3 includes a rectangular display panel 4 capable of displaying an image, a bezel 5 in a rectangular frame shape which is provided on a front face 3a side of the image display unit 3 and surrounds a display area of an image in the display panel 4, and a housing 6 which is provided on a back face 3b side of the image display unit 3 and receive a control device (not shown) and the like. The image display unit 3 is realized by, for example, a flat panel display unit such as a liquid crystal display unit, a plasma display unit or an organic EL (Electroluminescence) display unit.

As shown in FIGS. 1 and 2, the stand apparatus 1 includes a support member 11 comprised of columns 11a, a plurality of holding members 12 which are configured to be able to hold the image display unit 3 and mounted to the columns 11a so as to be capable of ascending and descending along the axial line of the columns 11a, and elevating and lowering sections 13 which elevate and lower movable holding members 12b described below in the plurality of holding members 12 along the axial line of the columns 11a.

The support member 11 is a member which supports the plurality of image display units 3 arranged in the vertical direction A1 in the multi-display apparatus 2 to be installed, and extends, for example, along a vertical direction. The support member 11 in this embodiment is configured by a pair of columns 11a extending in parallel, and three image display units 3 which are arranged in the vertical direction A1 in the multi-display apparatus 2 to be installed (hereinafter referred to as “image display unit group”) are supported by the pair of columns 11a. Furthermore, in this embodiment, three rows of the image display unit groups are provided in a transverse direction A2. Therefore, six columns 11a are provided in this embodiment.

Each of the columns 11a is formed to have a length longer than a size of the vertical direction A1 of the multi-display apparatus 2 to be installed, and has a material, a shape and a size selected and formed to have sufficient intensity and rigidity to support the plurality of image display units 3 arranged in the vertical direction A1. Each of the columns 11a is realized by a steel pipe in a cylindrical shape in this embodiment, but may be realized by a steel member in a columnar shape, a rectangular column shape or the like in other embodiment.

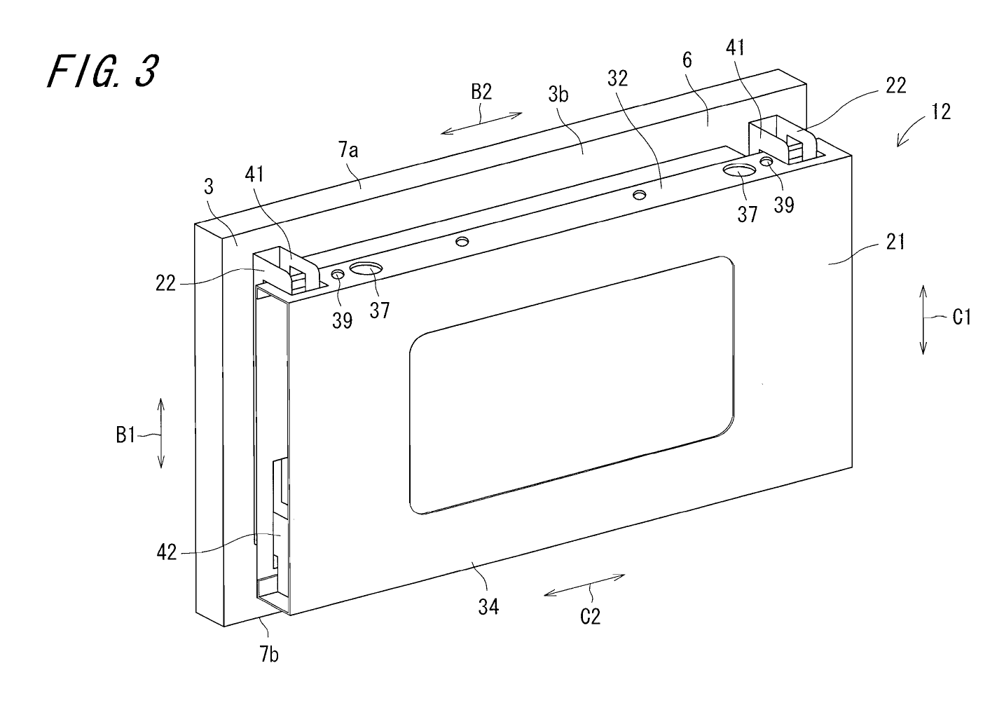

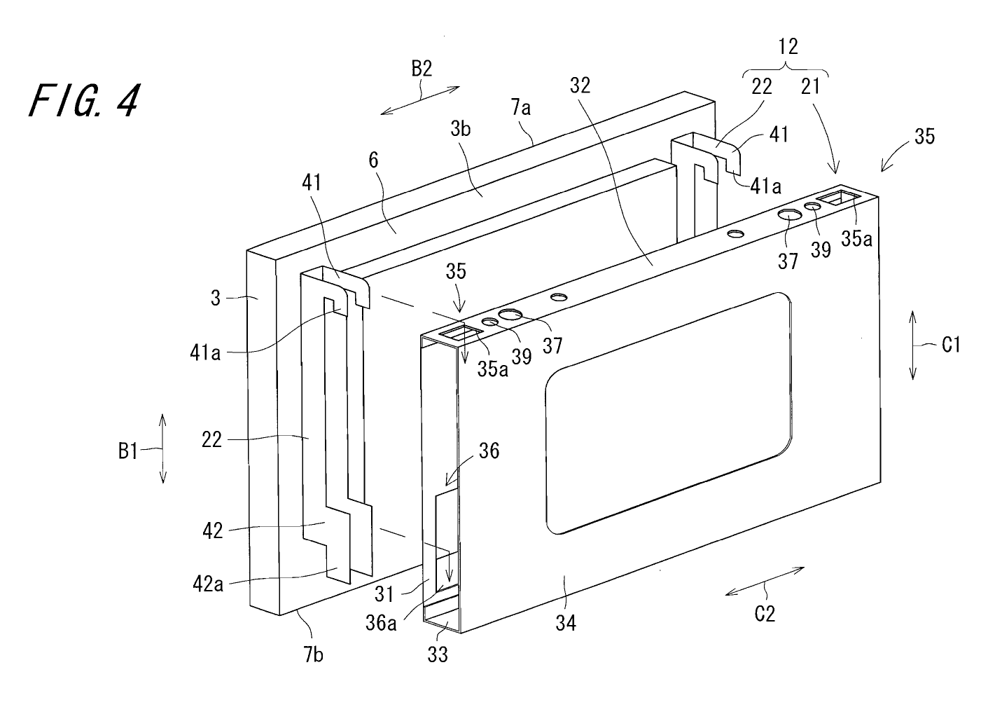

FIG. 3 is a perspective view of the holding member 12 to which the image display unit 3 is attached, seen from the back side, and FIG. 4 is an exploded perspective view showing the holding member 12. The holding member 12 is formed so that an overall size thereof becomes smaller than an overall size of the image display unit 3, and is attached to a substantially center of the back face 3b of the image display unit 3.

The holding member 12 is configured by a movable member 21 in an approximately quadrangular tube shape which is slightly smaller than the image display unit 3, and a pair of hooking members 22 fixed to the back face 3b of the image display unit 3 as shown in FIG. 4.

The hooking member 22 is a rod-shaped member formed to have a length shorter than a size of the short side direction B1 of the image display unit 3, in which first and second hooking sections 41 and 42 are provided at both end portions in a longitudinal direction thereof, respectively. Both the first and second hooking sections 41 and 42 are formed in an approximately L-shape so as to project in one direction perpendicular to the longitudinal direction of the hooking member 22 and to have leading end portions 41a and 42a bent at a right angle toward one side in the longitudinal direction. In the hooking member 22, the first hooking section 41 is arranged so that the leading end portion 41a is bent toward the second hooking section 42.

A pair of hooking members 22 which is formed in the same shape is fixedly fastened, respectively, using a fastener such as a bolt in a vicinity of the both end portions in a long side direction B2 in the back face 3b of the image display unit 3, in such attitudes that a longitudinal direction thereof matches the short side direction B1 of the image display unit 3 as well as the first hooking section 41 is positioned in the upper end portion 7a side of the image display unit 3 and the second hooking section 42 is positioned in the lower end portion 7b side of the image display unit 3.

On the other hand, the movable member 21 is comprised of four peripheral wall sections 31 to 34, and specifically is comprised of a front wall section 31 in a rectangular plate shape which has an overall size smaller than an overall size of the image display unit 3 when seen in a front view and faces the back face 3b of the image display unit 3 in a state of holding the image display unit 3, an upper wall section 32 and a lower wall section 33 in a rectangular plate shape each of which is coupled to a pair of parallel edge sides in the front wall section 31 and is erected vertically from the surface of one side in a thickness direction of the front wall section 31, and a back wall section 34 which is provided to face and be in parallel to the front wall section 31 and is coupled to the upper wall section 32 and the lower wall section 33.

Hereinafter, in the movable member 21, a direction perpendicular to the upper wall section 32 and the lower wall section 33 is referred to as a “height direction” with a reference sign of C1 denoted and a direction in parallel to the front wall section 31 and the back wall section 34 and perpendicular to the height direction C1 is referred to as a “width direction” with a reference sign of C2 denoted.

The upper wall section 32 is provided with a pair of first hooked sections 35 with an interval in the width direction C2 so as to correspond to an interval in the long side direction B2 of the pair of hooking members 22 fixed to the back face 3b of the image display unit 3. Each of the first hooked sections 35 is formed with a rectangular hooking hole 35a which penetrates in the thickness direction of the upper wall section 32 and in which the leading end portion 41a of the first hooking section 41 of the hooking member 22 is able to be inserted.

In addition, the front wall section 31 is provided with a pair of second hooked sections 36 with an interval in the width direction C2 so as to correspond to a position at which the pair of first hooking sections 35 is provided. Each of the second hooked sections 36 is formed with a slit 36a extending in the height direction C1 which penetrates in the thickness direction of the front wall section 31 and in which the second hooking section 42 of the hooking member 22 is able to be inserted.

With this configuration, each of the second hooking sections 42 of the pair of hooking members 22 attached to the image display unit 3 is inserted in each of a pair of slits 36a formed in the front wall section 31 of the movable member 21 and the pair of hooking members 22 is further displaced along the slit 36a in a direction where the leading end portion 42a of the second hooking section 42 is proximate to the lower wall section 33, so that the leading end portion 41a of the first hooking section 41 is inserted in the hooking hole 35a of the first hooked section 35, and the first hooking section 41 and the first hooked section 35 are hooked and, at the same time, the leading end portion 42a of the second hooking section 42 inserted downward from the slit 36a and the second hooked section 36 are hooked. That is, the hooking member 22 is hooked accompanied by relative displacement in the height direction C1 to the movable member 21.

When being hooked as described above, the first hooking section 41 and the first hooked section 35 as well as the second hooking section 42 and the second hooked section 36 are formed so that the movable member 21 and the hooking member 22 are coupled without looseness. In this manner, by coupling the movable member 21 and the hooking member 22, the image display unit 3 is held by the holding member 12.

At this time, the image display unit 3 is held by the holding member 12 in such attitudes that the short side direction B1 thereof and the height direction C1 of the movable member 21 are matched and the long side direction B2 thereof and the width direction C2 of the movable member 21 are matched.

Moreover, the movable member 21 is formed with two circular through holes 37 which penetrate in the thickness direction and has an inner diameter slightly larger than an outer diameter of the column 11a with an interval in the width direction C2 at the upper wall section 32 thereof, and two circular through holes 38 which penetrate in the thickness direction and has an inner diameter slightly larger than the outer diameter of the column 11a with an interval in the width direction C2 similarly at the lower wall section 33 so as to be coaxial with each of the through holes 37 formed in the upper wall section 32.

With this configuration, by inserting each of two columns 11a into the pair of through holes 37 and 38 formed in one side of the width direction C2 and the pair of through holes 37 and 38 formed in the other side of the width direction C2, the movable member 21 is mounted so as to be freely elevated and lowered along the axial line of the columns 11a.

Further, the movable member 21 is formed with two circular insertion holes 39 which penetrate in the thickness direction with an interval in the width direction C2 at the upper wall section 32 thereof, and two circular insertion holes 40 which penetrate in the thickness direction with an interval in the width direction C2 similarly at the lower wall section 33 so as to be coaxial with each of the insertion holes 39 formed in the upper wall section 32.

Each of the insertion holes 39 formed in the upper wall section 32 is formed so as to have an inner diameter allowing both a rod 65 in the elevating and lowering section 13 described below and a double nut 66 fixedly fastened to the rod 65 to be inserted. In addition, each of the insertion holes 40 formed in the lower wall section 33 is formed so as to have an inner diameter allowing the rod 65 in the elevating and lowering section 13 to be inserted and not allowing the double nut 66 fixedly fastened to the rod 65 to be inserted.

The holding member 12 is provided by the number of image display units 3 constituting the multi-display apparatus 2, and nine holding members 12 are provided in this embodiment. Moreover, as shown in FIG. 2, with respect to the pair of columns 11a, three holding members 12 are mounted to be arranged along the columns 11a in this embodiment.

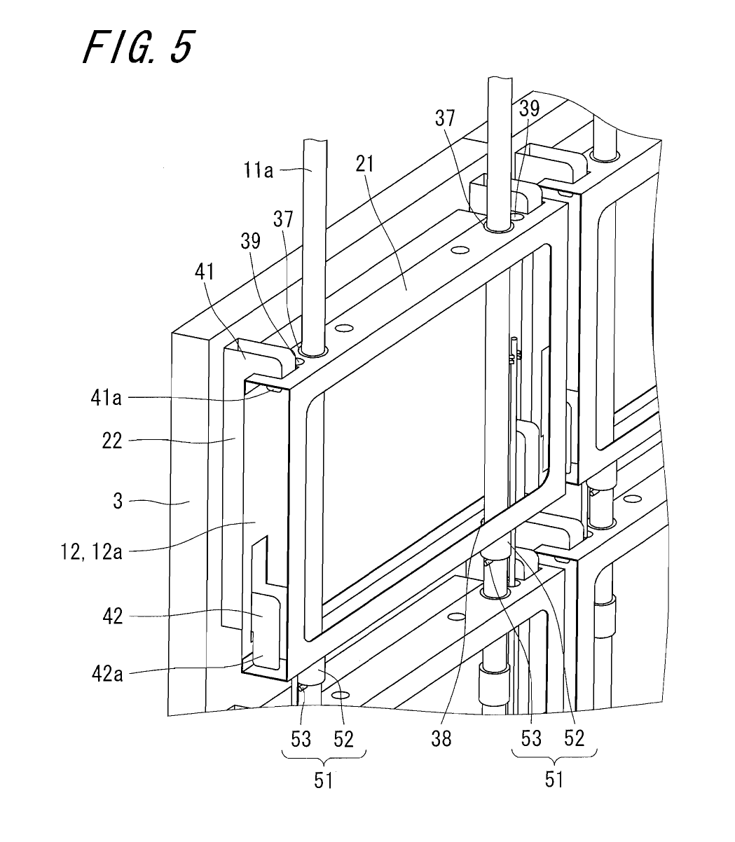

FIG. 5 is an enlarged perspective view of the holding member 12 arranged at the top stage, seen from the back side, which shows a state where the image display unit 3 is mounted. Among three holding members 12 mounted to the pair of columns 11a, the holding member 12 arranged at the top stage is supported by a displacement inhibiting section 51 provided in the columns 11a in a state of being inhibited to move downward in this embodiment.

As shown in FIG. 5, the displacement inhibiting section 51 includes a cylindrical sleeve 52 which has an inner diameter slightly larger than an outer diameter of the column 11a and has an outer diameter larger than an inner diameter of the through hole 38 formed in the lower wall section 33 of the movable member 21 and a locking pin 53 which is provided so as to penetrate in one radial direction of the column 11a at a predetermined position of height, and is configured so that the sleeve 52 is supported in a state of being inhibited to be displaced downward by the locking pin 53. The holding member 12 arranged at the top stage is arranged upward from the displacement inhibiting section 51 so as to be inhibited to be displaced downward from a position abutting against the sleeve 52.

Hereinafter, the holding member 12 which is inhibited to be displaced by the displacement inhibiting section 51 is referred to as a “reference holding member” with a reference sign of 12a denoted. On the other hand, remaining holding members 12 excluding the reference holding member 12a arranged at the top stage are referred to as “movable holding members” with a reference sign of 12b denoted.

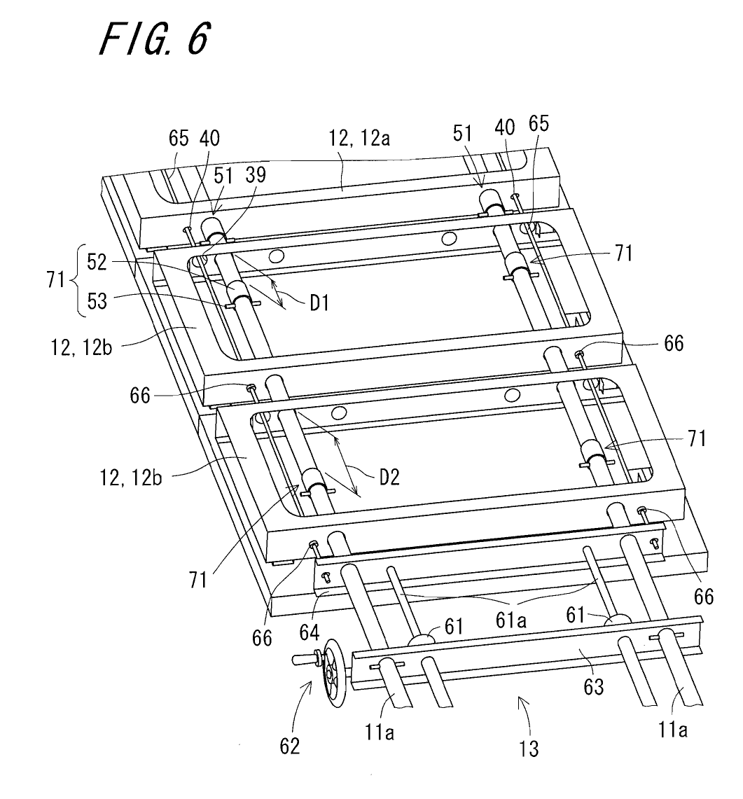

FIG. 6 is an enraged perspective view of the elevating and lowering section 13 provided in the pair of columns 11a, which shows a state where the multi-display apparatus 2 is constructed, that is a state where each of the image display units 3 arranged in the vertical direction A1 is adjacent to each other with no space.

The elevating and lowering section 13 includes a pair of hydraulic jacks 61 each of which has a movable shaft 61a, a handle 62 configured to drive the hydraulic jacks 61, a support plate 63 which supports the pair of hydraulic jacks 61, a movable plate 64 which is fixed to leading ends of the movable shafts 61a of the hydraulic jacks 61, a pair of rods 65 which is fixed to the movable plate 64 and extends along the columns 11a, and a plurality of double nuts 66 which are fixedly fastened at a predetermined position.

The pair of hydraulic jacks 61 is installed so that the leading ends of the movable shafts 61a face upward on the support plate 63 provided downward from the movable holding member 12b arranged at the bottom stage. The support plate 63 is provided being fixed to the pair of columns 11a in attitudes to be parallel to one imaginary plane perpendicular to the axial line of the columns 11a.

The pair of hydraulic jacks 61 is coupled to the single handle 62 provided in vicinity thereto and is configured, when the handle 62 is driven to rotate manually, to change the rotation to linear movement of the movable shafts 61a. That is, it is configured such that when the handle 62 is driven to rotate manually in one side, the movable shaft 61a of each of the hydraulic jacks 61 moves upward in conjunction therewith, and when the handle 62 is driven to rotate manually in the other side, the movable shaft 61a of each of the hydraulic jacks 61 moves downward in conjunction therewith. The pair of hydraulic jacks 61 is adjusted in advance so that the leading end of each of the movable shafts 61a moves with the equal position of height kept.

The movable plate 64 is mounted to the columns 11a so as to be capable of ascending and descending along the columns 11a in attitudes to be parallel to one imaginary plane perpendicular to the axial line of the columns 11a, in which the leading end of each of the movable shafts 61a of the pair of hydraulic jacks 61 is further fixed. Moreover, in the movable plate 64, the pair of rods 65 is fixedly fastened so as to extend upward from the movable plate 64. Each of the rods 65 is provided in parallel to the columns 11a so as to insert each of the insertion holes 39 and 40 of each of the movable holding members 12b and further insert the insertion hole 40 at the lower wall section 33 of the reference holding member 12a.

The double nut 66 is provided by the number of movable holding members 12b in each of the rods 65, and two double nuts 66 are provided relative to one rod 65 in this embodiment. Each of the double nuts 66 is fixedly fastened to the rod 65 being positioned so as to abut against the lower wall section 33 of each of the movable holding members 12b from downward in the state where the multi-display apparatus 2 is constructed as shown in FIG. 6. That is, in the state where the multi-display apparatus 2 is constructed, each of the movable holding members 12b is locked by the double nut 66 which is fixedly fastened to the rod 65 so as to be inhibited to move downward.

In addition, as shown in FIG. 6, each of the columns 11a is provided with a movement restricting section 71 configured in the same manner as the displacement inhibiting section 51 described above, that is, configured by the sleeve 52 and the locking pin 53 for each movable holding member 12b. The movement restricting section 71 is installed between the upper wall section 32 and the lower wall section 33 of the movable holding member 12b, and specifically is installed so that the upper wall section 32 of the movable holding member 12b is separated from an upper end face of the sleeve 52 by a predetermined distance in the state where the multi-display apparatus 2 is constructed.

More specifically, the movement restricting section 71 is installed such that in the movable holding members 12b vertically adjacent to each other, a distance D2 between the upper wall section 32 of the movable holding member 12b arranged at the lower stage and the upper end face of the sleeve 52 becomes larger than a distance D1 between the upper wall section 32 of the movable holding member 12b arranged at the upper stage and the upper end face of the sleeve 52.

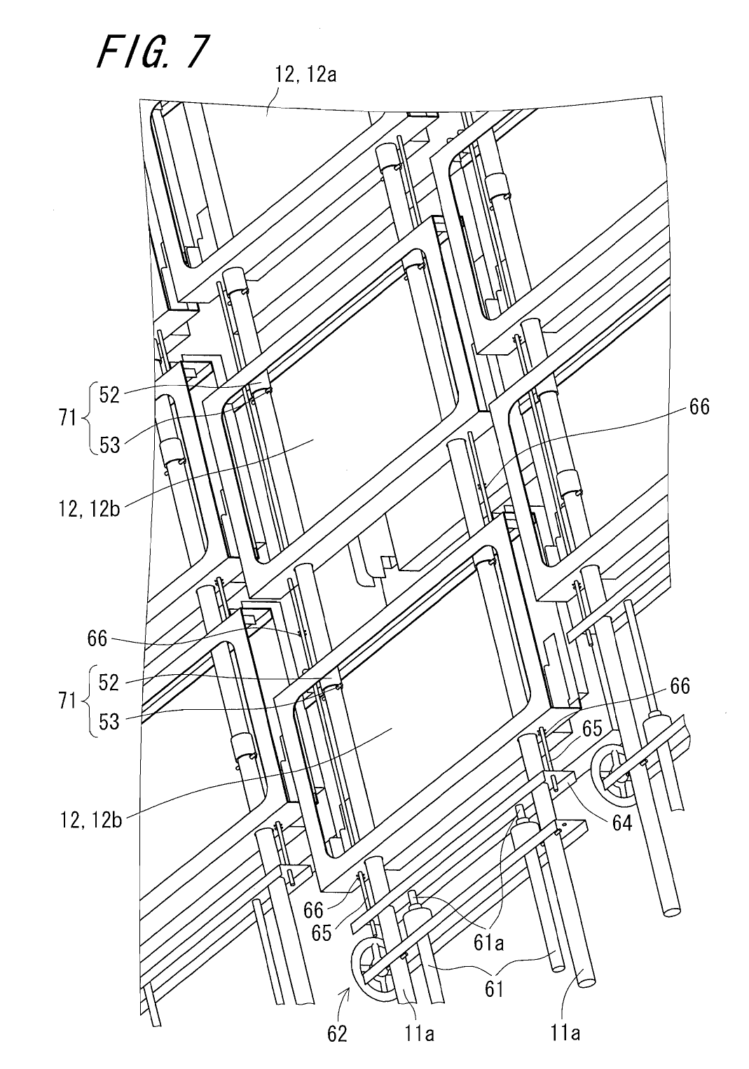

FIG. 7 is a perspective view showing a state where the movable plate 64 lowers from the state where the multi-display apparatus 2 is constructed shown in FIG. 6. As shown in FIG. 7, when the handle 62 is operated to lower the movable plate 64, the rod 65 and the double nut 66 which is fixedly fastened to the rod 65 also lower accordingly, so that the movable holding member 12b locked by the double nut 66 also lowers in conjunction therewith.

Here, in the state where the multi-display apparatus 2 is constructed, when the distance between the upper wall section 32 of the movable holding member 12b arranged at the middle stage and the upper end face of the sleeve 52 is D1 and the distance between the upper wall section 32 of the movable holding member 12b arranged at the bottom stage and the upper end face of the sleeve 52 is D2 (wherein, D1<D2), in a state where a descending distance d of the movable plate 64 is less than D1, the two movable holding members 12b lower in conjunction with the movable plate 64, so that a space of the distance d is formed between the image display unit 3 at the top stage and the image display unit 3 at the middle stage.

When the movable plate 64 further lowers so that the descending distance d equals to D1, the upper wall section 32 of the movable holding member 12b arranged at the middle stage abuts against the upper end face of the sleeve 52 of the movement restricting section 71, and since then, the downward movement of the movable holding member 12b arranged at the middle stage is restricted. At this time, a space of an interval D1 is formed between the image display unit 3 at the top stage and the image display unit 3 at the middle stage.

In a state where the movable plate 64 further lowers so that the descending distance d is larger than D1 and less than D2, only the movable holding member 12b at the bottom stage lowers in conjunction with the movable plate 64, so that a space of an interval d-D1 is formed between the image display unit 3 at the middle stage and the image display unit 3 at the bottom stage.

When the movable plate 64 further lowers so that the descending distance d equals to D2, the upper wall section 32 of the movable holding member 12 arranged at the bottom stage abuts against the upper end face of the sleeve 52 of the movement restricting section 71, and the downward movement of the movable holding member 12b arranged at the bottom stage is restricted. At this time, a space of an interval D2-D1 is formed between the image display unit 3 at the middle stage and the image display unit 3 at the bottom stage.

Accordingly, by selecting the distances D1 and D2 between the upper wall section 32 of the movable holding member 12b and the upper end face of the sleeve 52 so as to be larger than the upward movement distance required for separating the hooking member 22 fixed to the image display unit 3 from the movable member 21, it is possible to remove only the image display unit 3 arranged at the middle stage or the bottom stage.

The distances D1 and D2 between the upper wall section 32 of the movable holding member 12b and the upper end face of the sleeve 52 are selected, for example, so that the interval D1 of the space formed between the image display unit 3 at the top stage and the image display unit 3 at the middle stage equals to the interval D2-D1 of the space formed between the image display unit 3 at the middle stage and the image display unit 3 at the bottom stage.

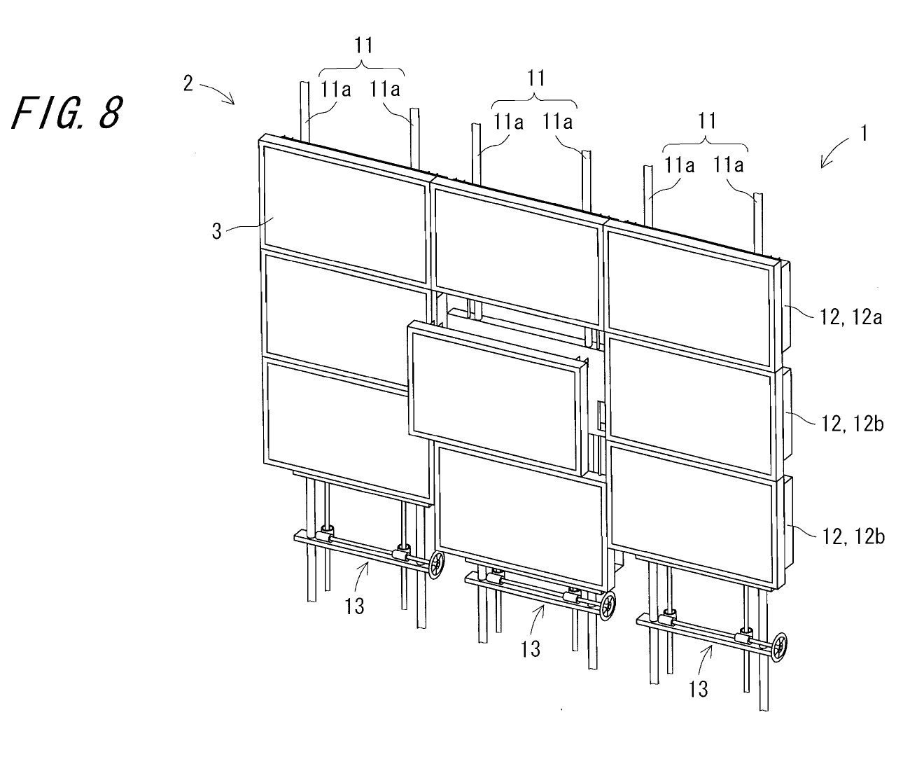

FIG. 8 is a perspective view showing a state where the image display unit 3 arranged at the middle stage is removed in the multi-display apparatus 2. As described above, according to this embodiment, when the image display unit 3 is removed from the multi-display apparatus 2 for executing maintenance, even if the image display unit 3 to be removed is arranged at the middle stage or the bottom stage, it is possible to form a space between the image display unit 3 to be removed and the image display unit 3 arranged at its upper stage, thus making it possible to remove only the image display unit 3 to be removed. Accordingly, it is possible to reduce labor and time required for removing the image display unit 3 other than the removal object and to improve maintainability of the multi-display apparatus 2.

In the embodiment described above, the elevating and lowering section 13 is configured to be operated manually, but without limitation to the manual operation, may be configured to be operated electrically.

Moreover, it is configured such that the hydraulic jacks 61 and the movable plate 64 are arranged downward from the movable holding member 12b in the embodiment described above, but without limitation thereto, may be configured such that the hydraulic jacks 61 and the movable plate 64 are arranged upward from the reference holding member 12a. In this case, it is possible to realize by extending the rod 65 upward to fix to the movable plate 64.

Moreover, the hydraulic jack 61 is used as an apparatus for moving the movable plate 64 in the embodiment described above, but a screw jack, a hydraulic cylinder, a pneumatic cylinder, a winch or the like may be used in place of the hydraulic jack 61 in another embodiment. When the winch is used, it is possible to realize by using a wire rope capable of being wound in place of the rod 65. In addition, when the winch is installed downward from the movable holding member 12b, it is possible to realize by attaching a pulley upward from the reference holding member 12a.

Moreover, the multi-display apparatus 2 which is constituted by arranging nine image display units 3 in three rows and three columns in a matrix is to be installed in the embodiment described above, but without limitation thereto, only with a multi-display apparatus in which a plurality numbers of image display units 3 are arranged in the vertical direction A1, it is possible to improve maintainability by using the stand apparatus 1 according to the technology.

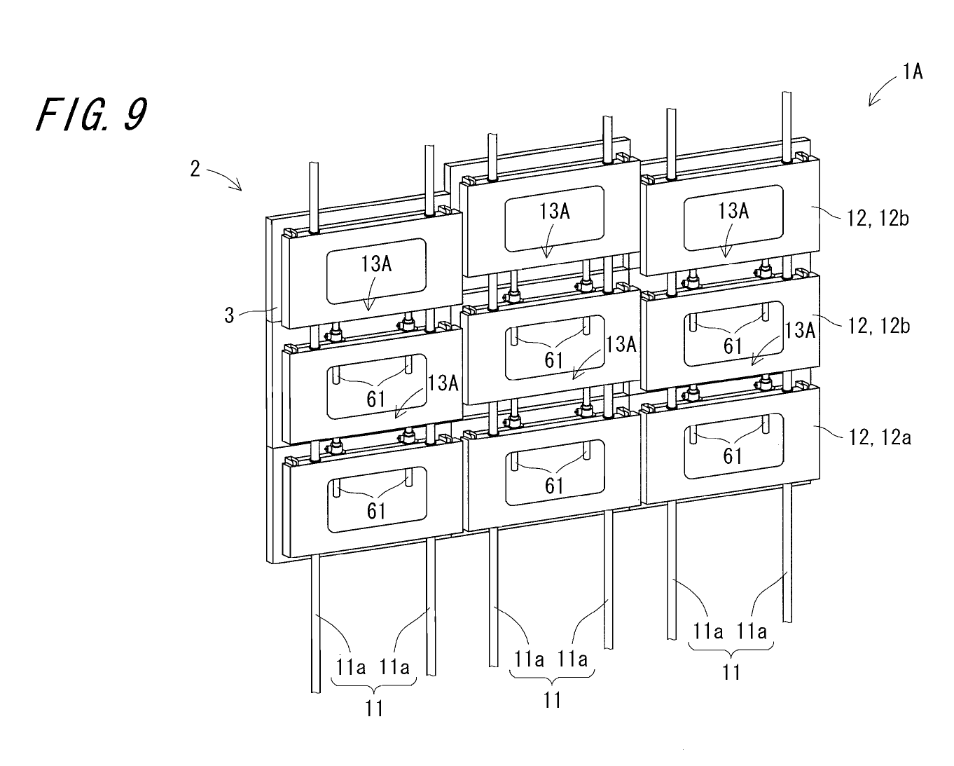

FIG. 9 is a perspective view of a state where a stand apparatus 1A according to another embodiment supports the multi-display apparatus 2, seen from a back side. Since the stand apparatus 1A according to this embodiment has a configuration equivalent to that of the stand apparatus 1 according to the embodiment described above, the same configuration will be denoted by the same reference sign and the description thereof will be omitted.

In this embodiment, differently from the embodiment described above, among three holding members 12 mounted to a pair of columns 11a, the holding member 12 arranged at the bottom stage is supported in a state of being inhibited to move downward by the displacement inhibiting section 51 provided in the columns 11a. That is, the reference holding member 12a is provided at the bottom stage, and the movable holding member 12b is provided upward therefrom.

In this embodiment, elevating and lowering sections 13A are provided in remaining holding members 12 except the holding member 12 arranged at the top stage, out of the plurality of holding members 12, respectively. Each of the elevating and lowering sections 13A includes a pair of hydraulic jacks 61 each of which has the movable shaft 61a, and the pair of hydraulic jacks 61 is installed so that the leading ends of the movable shafts 61a face upward on the upper wall section 32 of the movable member 21 in the holding member 12. Accordingly, by driving the pair of hydraulic jacks 61 to move the movable shafts 61a upward, it is possible to press up and move upward one or a plurality of movable holding members 12b above which the movable shafts 61a are arranged.

In this manner, according to this embodiment, when the image display unit 3 is removed from the multi-display apparatus 2 for executing maintenance, even if the image display unit 3 to be removed is arranged at the middle stage or the bottom stage, it is possible to form a space with the image display unit 3 arranged at its upper stage by operating the elevating and lowering section 13 of the holding member 12 to which the image display unit 3 to be removed is attached. This makes it possible to remove only the image display unit 3 to be removed. Accordingly, it is possible to reduce labor and time required for removing the image display unit 3 other than the removal object and to improve maintainability of the multi-display apparatus 2.

The technology may be embodied in other specific forms without departing from the spirit or essential characteristics thereof. The present embodiments are therefore to be considered in all respects as illustrative and not restrictive, the scope of the technology being indicated by the appended claims rather than by the foregoing description and all changes which come within the meaning and the range of equivalency of the claims are therefore intended to be embraced therein.

What is claimed is:

1. A stand apparatus for installing a multi-display apparatus having a configuration such that a plurality of image display units are arranged in a plane, comprising:
a column;
a plurality of holding members configured to be able to hold the image display units and be mounted to the column so as to be capable of ascending and descending along an axial line of the column, the plurality of holding members including
a reference holding member supported by the column in a state of being inhibited to move at least in a direction of descending along the axial line of the column, and
a movable holding member or members supported by the column so as to be freely elevated and lowered along the axial line of the column; and
an elevating and lowering section or sections configured so as to elevate and lower the movable holding member or members along the axial line of the column.

2. The stand apparatus of claim 1, wherein the plurality of holding members each include a movable member attached to the column and a hooking member configured so as to be attachable to the image display unit and capable of being hooked with the movable member, and
the hooking member is configured to be hooked accompanied by displacement along the axial line of the column with respect to the movable member in a state of being attached to the column.

3. The stand apparatus of claim 1, wherein the movable holding members are arranged downward from the reference holing member,
the column is provided with movement restricting members configured so as to restrict movement in a descending direction of the movable holding members for each of the movable holding members, and
the movement restricting members are disposed so that at the lower stage the movable holding members are arranged, the longer movable distances of the movable holding members in the descending direction are.

4. The stand apparatus of claim 1, wherein the movable holding members are arranged upward from the reference holing member, and
the elevating and lowering sections are installed in remaining holding members except a holding member arranged at a top stage, out of the plurality of holding members, respectively.

5. The stand apparatus of claim 1, wherein the elevating and lowering section includes any one of a hydraulic jack, a screw jack, a pneumatic cylinder, a hydraulic cylinder and a winch.
